(19) United States
(12) Patent Application Publication
(10) Pub. No.: US 2017/0059679 A1
(43) Pub. Date: Mar. 2, 2017

(54) MAGNETIC RESONANCE IMAGING APPARATUS

(71) Applicant: Toshiba Medical Systems Corporation, Otawara-shi (JP)

(72) Inventors: Hiroki KONDO, Nasushiobara (JP); Naho IMAMURA, Nasushiobara (JP); Masaaki UMEDA, Sakura (JP)

(73) Assignee: Toshiba Medical Systems Corporation, Otawara-shi (JP)

(21) Appl. No.: 15/152,685

(22) Filed: May 12, 2016

(30) Foreign Application Priority Data
Aug. 31, 2015 (JP) 2015-171000

(51) Int. Cl. G01R 33/56

(52) U.S. Cl. CPC G01R 33/56

(57) ABSTRACT

According to at least one of embodiments, a magnetic resonance imaging apparatus includes an RF coil equipped with a plurality of coil elements and processing circuitry configured to determine a risk of generating artifact caused by mixture of a magnetic resonance signal outside an imaging region of an object, based on imaging conditions and to select at least one coil element used for generating an image of the object from the plurality of coil elements, based on a result of determination of the risk of generating artifact.

### CROSS-REFERENCE TO RELATED APPLICATIONS

This application is based upon and claims the benefit of priority from Japanese Patent Application No. 2015-171000 filed on Aug. 31, 2015, the entire contents of which are incorporated herein by reference.

### FIELD

Embodiments described herein relate generally to a magnetic resonance imaging apparatus.

### BACKGROUND

A magnetic resonance imaging apparatus is an imaging apparatus configured to magnetically excite nuclear spin of a patient placed in a static magnetic field with an RF (Radio Frequency) signal having the Larmor frequency and reconstruct an image based on magnetic resonance signals generated due to the excitation.

In an image obtained by a magnetic resonance imaging apparatus, a false image called an artifact is sometimes mixed. Artifacts in magnetic resonance imaging are generated by various factors such as incompleteness of a magnetic resonance imaging apparatus, inappropriate setting of imaging parameters, and body motions of an object.

In a magnetic resonance imaging apparatus, various measures to eliminate or suppress those various types of artifacts have been conventionally taken.

In those various types of artifacts, an artifact generated by nonlinearity of a gradient magnetic field is known.

### BRIEF DESCRIPTION OF THE DRAWINGS

In the accompanying drawings:

FIG. 1 is a block diagram illustrating overall configuration of a magnetic resonance imaging apparatus of the first embodiment;

FIG. 2A and FIG. 2B are schematic diagrams illustrating the RF coil 20 mounted on the abdominal side in FIG. 1 configured as a body coil;

FIG. 3A and FIG. 3B are schematic diagrams illustrating the RF coil 20 mounted on the back side in FIG. 1 configured as a spine coil;

FIG. 4A to FIG. 4D are schematic graphs of intensity of a gradient magnetic field illustrating a generation mechanism of annefact;

FIG. 5 is a block diagram illustrating detailed configuration of the magnetic resonance imaging apparatus in the first embodiment;

FIG. 6 is a flowchart illustrating an operation performed by the magnetic resonance imaging apparatus in the first embodiment;

FIG. 7A and FIG. 7B are schematic diagrams illustrating an operational concept of the magnetic resonance imaging apparatus in the first embodiment;

FIG. 8 a flowchart illustrating an operation performed by the magnetic resonance imaging apparatus in the second embodiment; and

FIG. 9A and FIG. 9B are schematic diagrams illustrating an operational concept of the magnetic resonance imaging apparatus in the second embodiment.

### DETAILED DESCRIPTION

Hereinafter, embodiments of the present invention will be described with reference to the accompanying drawings.

According to at least one of embodiments, a magnetic resonance imaging apparatus includes an RF coil equipped with a plurality of coil elements; and processing circuitry configured to determine a risk of generating an artifact caused by mixture of a magnetic resonance signal outside an imaging region of an object, based on imaging conditions and to select at least one coil element used for generating an image of the object from the plurality of coil elements, based on a result of determination of the risk of generating artifact.

### First Embodiment

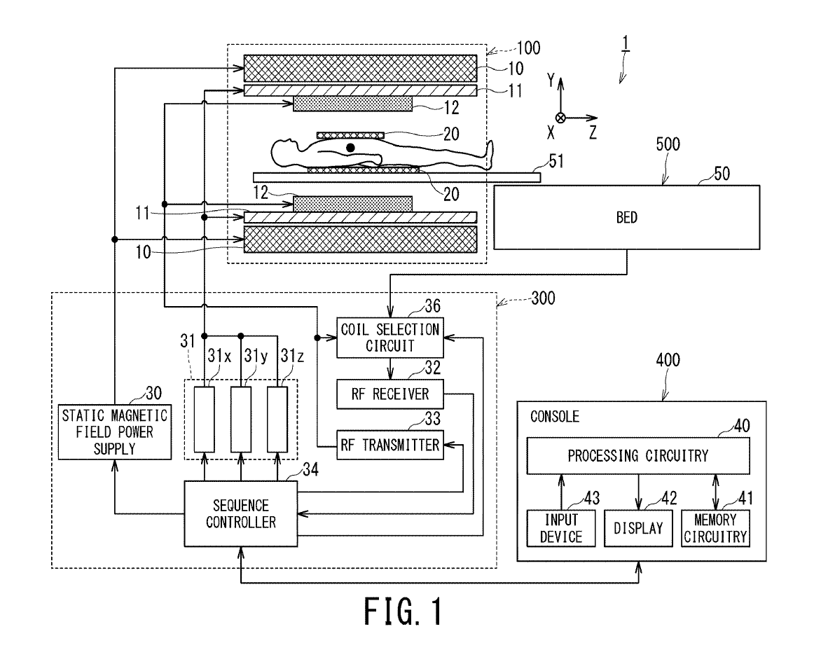

FIG. 1 is a block diagram illustrating overall configuration of a magnetic resonance imaging apparatus 1 of the first embodiment. The magnetic resonance imaging apparatus 1 includes a gantry 100, a bed 500, a control cabinet 300, a console 400, and RF (Radio Frequency) coils 20.

The gantry 100 includes a static magnetic field magnet 10, a gradient coil 11, and a WB (Whole Body) coil 12, and these components are included in a cylindrical housing. The bed 200 includes a bed body 50 and a table 51.

The control cabinet 300 includes a static magnetic field power supply 30, three gradient coil power supplies 31 (to be exact, 31x for an X-axis, 31y for a Y-axis, and 31z for a Z-axis), a coil selection circuit 36, an RF receiver 32, an RF transmitter 33, and a sequence controller 34.

The console 400 includes processing circuitry 40, memory circuitry 41, an input device 43, and a display 42. The console 400 functions as a host computer.

The static magnetic field magnet 10 of the gantry 100 is substantially in the form of a cylinder, and generates a static magnetic field inside a bore into which an object, e.g., a patient is moved. The bore is a space inside the cylindrical structure of the gantry 100. The static magnetic field magnet 10 includes a superconducting coil inside, and the superconducting coil is cooled down to an extremely low temperature by liquid helium. The static magnetic field magnet 10 generates the static magnetic field by supplying the superconducting coil with the electric current provided from the static magnetic field power supply 30 in an excitation mode. Afterward, the static magnetic field magnet 10 shifts to a permanent current mode, and the static magnetic field supply 30 is separated. Once it enters the permanent current mode, the static magnetic field magnet 10 continues to generate a strong static magnetic field for a long time, e.g., over one year.

In FIG. 1, the blackly filled circle on the chest of an object indicates the position of the magnetic field center.

The gradient coil 11 is also substantially in the form of a cylinder, and is fixed to the inside of the static magnetic field magnet 10. This gradient coil 11 applies gradient magnetic fields to an object in the respective directions of the X-axis, the Y-axis, and the Z-axis, by using the electric currents supplied from the gradient coil power supplies 31x, 31y, and 31z.

The bed body 50 of the bed 500 can move the table 51 upward and downward in the vertical directions and can move the table 21 in the horizontal direction. The bed body 50 moves the table 51 with an object loaded thereon to a predetermined height before imaging. Afterward, at the time of imaging, the bed body 50 moves the table 51 in the horizontal direction so as to move the object inside the bore.

The WB coil 12 is also referred to as a whole body coil, is shaped approximately in the form of a cylinder so as to surround an object, and is fixed to the inside of the gradient coil 11. The WB coil 12 applies each RF pulse transmitted from the RF transmitter 33 to an object, and receives MR (Magnetic Resonance) signals emitted from the object due to excitation of hydrogen nuclei.

As shown in FIG. 1, the magnetic resonance imaging apparatus 1 includes RF coils 20 aside from the WB coil 12. Each of the RF coils 20 is a coil to be placed adjacent to a body surface of an object. Each of the RF coils 20 includes plural coil elements described below. Since these plural coil elements are arranged in an array inside each of the RF coils 20, these plural coil elements are sometimes collectively referred to as PAC (Phased Array Coils). Various types of RF coil are known as the RF coils 20.

For example, a body coil to be mounted on the chest, abdomen, and/or legs of an abject as shown in FIG. 1 is known as a type of the RF coils 20. Additionally, a spine coil to be mounted on the back of an abject as shown in FIG. 1 is known as a type of the RF coils 20. Further, a head coil used for imaging a head of an object, a foot coil used for imaging a foot of an object, a wrist coil used for imaging a wrist of an object, a knee coil for imaging a knee of an object, and a shoulder coil used for imaging a shoulder of an object are also known as other types of the RF coils 20. Although many types of the RF coils 20 are receive-only surface coils, some types of head coil are configured to implement both functions of applying RF pulses and receiving MR signals. Each of the RF coils 20 is configured to be detachable from the table 51 via a cable.

The RF transmitter 33 generates RF pulses based on commands inputted from the sequence controller 34. The generated RF pulses are transmitted to the WB coil 12 and applied to an object. MR signals are emitted from the object due to application of each RF pulse. These MR signals are received by the RF coils 20 and/or the WB coil 12.

The MR signals received by the RF coils 20, i.e., the MR signals detected by the respective coil elements inside the RF coils 20 are transmitted to the coil selection circuit 36 via cables provided in the table 51 and the bed body 50. The output pathway of each of the coil elements and/or the output pathway of the WB coil 12 is referred to as a channel.

Thus, each of MR signals which are outputted from respective coil elements and the WB coil 12 is also referred to as a channel signal. The channel signal received by the WB coil 12 is also transmitted to the coil selection circuit 36.

The coil selection circuit 36 selects channel signals outputted from the RF coils 20 or the channel signal outputted from the WB coil 12, according to control signals inputted from the sequence controller 34 or the console 400.

The selected channel signals are transmitted to the RF receiver 32. The RF receiver 32 performs A/D (Analog to Digital) conversion on the channel signals, i.e., MR signals, and outputs the digitized MR signals to the sequence controller 34. The digitized MR signals are also referred to as raw data. Incidentally, the A/D conversion of the MR signals may be performed inside each of the RF coils 20 or in the coil selection circuit 36.

The sequence controller 34 performs a scan of an object by driving the gradient coil power supplies 31x, 31y, and 31z, the RF transmitter 33, and the RF receiver 32, under the control of the console 400. When the sequence controller 34 receives raw data from the RF receiver 32 by performing a scan, the sequence controller 34 transmits the raw data to the console 400.

The sequence controller 34 includes non-illustrated processing circuitry. The processing circuitry of the sequence controller 34 may be configured of hardware such as an FPGA (Field Programmable Gate Array) or an ASIC (Application Specific Integrated Circuit). Alternatively or additionally, the processing circuitry of the sequence controller 34 may be configured to include a processor executing predetermined programs.

The console 400 includes memory circuitry 41, an input device 43, a display 42, and processing circuitry 40. The memory circuitry 41 is a memory medium including external memory devices such as a ROM (Read Only Memory), a RAM (Random Access Memory), a HDD (Hard Disk Drive) and an optical disc. The memory circuitry 41 stores various types of programs executed by a processor of the processing circuitry 40 in addition to various types of information and data.

The input device 43 is configured of, for example, a mouse, a keyboard, a trackball, and a touch panel, and includes various types of devices in order for an operator to input various types of information and data. The display 42 is a display device such as a liquid crystal display panel, a plasma display panel, and an organic EL (light emitting) display.

The processing circuitry 40 is, for example, a circuit equipped with a CPU and/or a special-purpose or general-purpose processor. This processor implements various types of functions described below by executing various types of programs stored in the memory circuitry 41. The processing circuitry 40 may be configured as hardware such as an FPGA and an ASIC. Various types of functions of the processing circuitry 40 can be implemented by such hardware. Additionally, the processing circuitry 40 may implement various types of functions by combining hardware processing and software processing by a processor and programs.

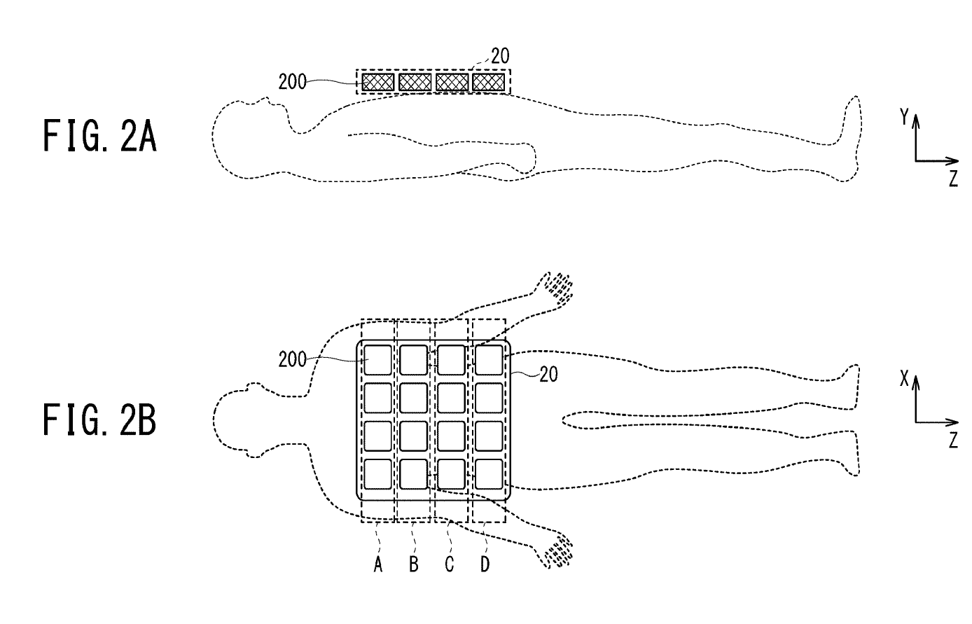

FIG. 2A and FIG. 2B are schematic diagrams illustrating the RF coil 20 mounted on the abdominal side in FIG. 1 configured as a body coil. Although the RF coil 20 as a body coil can be mounted, for example, so as to cover the chest region of an object as shown in FIG. 1 and FIG. 2A, the RF coil 20 as a body coil can also be mounted so as to cover the abdominal region and/or the leg region of an object. Additionally or alternatively, two or three body coils may be arranged along the head-foot direction of an object.

As shown in FIG. 2B, the RF coil 20 as a body coil includes plural the coil elements 200, i.e., plural loop coils. The coil elements 200 are planarly arranged in an array along the head-foot direction (i.e., the Z-axis direction) and along the right-to-left direction (i.e., the X-axis direction) of an object. In the case illustrated in FIG. 2A and FIG. 2B, a total of sixteen coil elements 200 are planarly arranged in four rows in the head-foot direction and in four columns in the right-to-left direction of an object like a matrix.

These coil elements 200 can be divided into plural arrangement units in the head-foot direction. Hereinafter, each of these arrangement units is referred to as a coil section or simply referred to as a section. One coil section includes plural coil elements 200 arranged in the right-to-left direction of an object.

The RF coil 20 illustrated in FIG. 2A and FIG. 2B includes four coil sections arranged in the head-foot direction, i.e., a coil section A, a coil section B, a coil section C, and a coil section D. Each of the coil sections A, B, C, and D includes four coil elements 200 arranged in the right-to-left direction of an object.

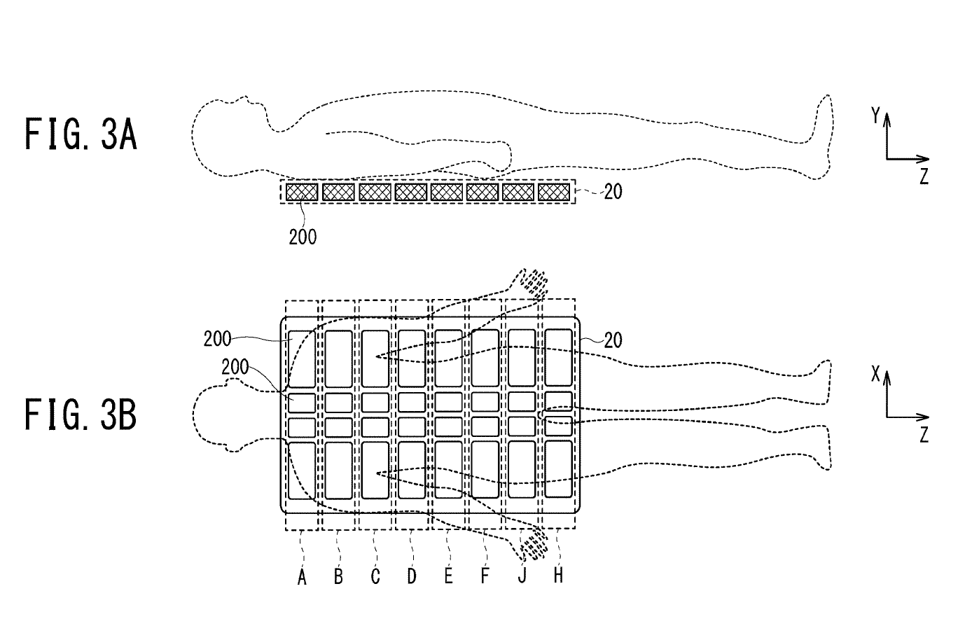

FIG. 3A and FIG. 3B are schematic diagrams illustrating the RF coil 20 mounted on the back side in FIG. 1 configured as a spine coil. The RF coil 20 as a spine coil is attached between the back of an object and the table 51 as shown in FIG. 1 and FIG. 3A.

As shown in FIG. 3B, the RF coil 20 as a spine coil also includes plural coil elements 200, i.e., plural loop coils. The coil elements 200 of the spine coil are planarly arranged in an array along the head-foot direction (i.e., the Z-axis direction) and along the right-to-left direction (i.e., the X-axis direction) of an object. In the case illustrated in FIG. 3A and FIG. 3B, a total of thirty-two coil elements 200 are planarly arranged in eight rows in the head-foot direction and in four columns in the right-to-left direction of an object like a matrix.

Note that all the coil elements 200 of the RF coil 20 as a body coil shown in FIG. 2A and FIG. 2B are unified in size. By contrast, in the case of the RF coil 20 as a spine coil shown in FIG. 3A and FIG. 3B, the sixteen coil elements 200 in the central two columns in the right-to-left direction are smaller in size than the remaining sixteen coil elements 200 arranged in the outer two columns in the right-to-left direction.

The plural coil elements 200 of the RF coil 20 as a spine coil are also divided into plural coil sections in the body axis direction. In the case shown in FIG. 3A and FIG. 3B, thirty-two coil elements 200 are divided into eight coil sections including coil sections A to H.

The magnetic resonance imaging apparatus 1 of the present embodiment is configured to select specific coil element(s) 200 used for imaging from all the coil elements 200 of the RF coil(s) 20 in order to avoid or suppress an artifact attributable to nonlinearity of each gradient magnetic field. The specific coil element(s) 200 may be selected in an individual coil element unit or may be selected in the above-described coil section unit. Hereinafter, a case where specific coil elements are selected in a coil section unit will be described as one of the embodiments.

Prior to description of an operation performed by the magnetic resonance imaging apparatus 1 of the present embodiment, an artifact called “annefact”, which should be eliminated or suppressed, will be described.

Annefact is an artifact generated when MR signals of a region outside an imaging region, i.e., outside an FOV (Field of View) are mixed into the FOV due to nonlinearity of each gradient magnetic field. To be precise, annefact is caused by nonlinearity of a composite magnetic field of a static magnetic field and each gradient magnetic field. Although this artifact is also referred to as an “annefact artifact”, a “cusp artifact”, a “fold-over artifact”, a “feather artifact”, or a “peripheral-signal artifact”, aside from the term “annefact”, any one of these terms means the artifact caused by the same generation mechanism. Hereinafter, this artifact will be described simply as the “annefact”, in a unified way.

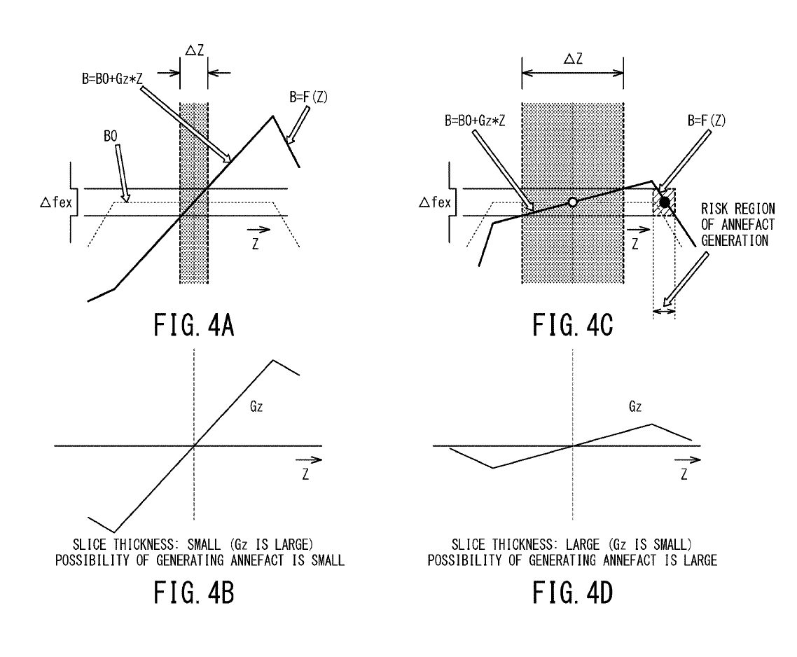

FIG. 4A to FIG. 4D are schematic graphs of intensity variation of a magnetic field in the Z-axis position illustrating the generation mechanism of annefact in detail. In each of FIG. 4A to FIG. 4D, the horizontal direction indicates a position in the Z direction, the vertical direction indicates magnetic field intensity, and the center position of the Z direction corresponds to a position where intensity of the gradient magnetic field Gz in the Z-axis direction becomes zero.

FIG. 4A and FIG. 4B correspond to a condition where slice thickness ΔZ in the Z-axis direction is set to a small value. FIG. 4B illustrates intensity of the gradient magnetic field Gz in the Z-axis direction. FIG. 4A illustrates intensity of a magnetic field B combined by the static magnetic field B0 and the gradient magnetic field Gz in the Z-axis direction shown in FIG. 4B.

When a frequency band of an excitation pulse is defined as Δfex and intensity of the gradient magnetic field in the Z-axis direction is defined as Gz, the slice thickness ΔZ can be indicated by the following the formula (1).

ΔZ={(2π)/γ}*{(Δfex)/Gz} Formula (1)

Here, γ is a constant referred to as a magnetogyric ratio. As is clear from the formula (1), the slice thickness ΔZ is inversely proportional to the intensity of the gradient magnetic field Gz. Thus, in order to reduce the slice thickness ΔZ, it is required to set the intensity of the gradient magnetic field Gz to a large value. FIG. 4B indicates that a slope of the linear region, i.e., a slope of the gradient magnetic field in the Z-axis direction around the magnetic field center is large corresponding to large gradient magnetic field intensity Gz.

FIG. 4C and FIG. 4D correspond to a condition where slice thickness ΔZ in the Z-axis direction is set to a large value. FIG. 4D, similarly to FIG. 4B, illustrates intensity of the gradient magnetic field Gz in the Z-axis direction. Further, FIG. 4C, similarly to FIG. 4A illustrates intensity of a magnetic field B combined by the static magnetic field B0 and the gradient magnetic field Gz in the Z-axis direction shown in FIG. 4D.

In order to increase the slice thickness ΔZ, it is required to set the gradient magnetic field intensity Gz to a small value. FIG. 4D indicates that a slope of the linear region, i.e., a slope of the gradient magnetic field in the Z-axis direction around the magnetic field center is small corresponding to small gradient magnetic field intensity Gz.

In a predetermined range around the magnetic field center, the magnetic field B is expressed by B(Z)=B0+Gz*Z, indicating that the magnetic field B(Z) linearly changes in proportion to the distance Z from the magnetic field center. Here, B0 is intensity of the static magnetic field.

However, in a region far away from the magnetic field center, both the gradient magnetic field and the static magnetic field non-linearly changes. For example, as shown in FIG. 4B and FIG. 4D, though the gradient magnetic field Gz has a positive slope within a predetermined range around the magnetic field center, the gradient magnetic field has a negative slope and non-linearly changes outside the predetermined range around the magnetic field center. Additionally, as shown in FIG. 4A and FIG. 4C, though the intensity of the static magnetic field is constant within a predetermined range around the magnetic field center, the intensity of the static magnetic field shows nonlinearity and decreases outside the predetermined range around the magnetic field center.

Here, the position of the FOV in the Z-axis direction being set within the linear region is defined as Zf, and the Z-axis position in the non-linear region outside the FOV is defined as Zr. Further, magnetic field intensity in the non-linear is assumed to be indicated by a nonlinear function F(Z). Then, the magnetic field intensity B(Zf) in the linear region is indicated by the following formula (2), and the magnetic field intensity B(Zr) in the nonlinear region is indicated by the following formula (3).

B(Zf)=B0+Gz*Zf (Linear Region):Formula (2)

B(Zr)=F(Zr) (Non-Linear region):Formula (3)

Here, the magnetic resonance frequency, i.e., the frequency f of MR signals is indicated by f=(½π)*γ*B. Thus, when the range of the magnetic field intensity B(Zf) in the linear region completely or partially matches with the range of the magnetic field intensity B(Zf) in the non-linear region, the frequency range of MR signals emitted from the linear region completely or partially matches with the frequency range of MR signals emitted from the non-linear region.

In this case, even if the imaging region, i.e., the FOV is set within the linear region, there is a possibility that MR signals emitted from the non-linear region far away from the FOV are mixed into the FOV as MR signals having the same frequency as the MR signals emitted from the FOV. The artifact mixed from a region outside the FOV into the FOV under the above-described mechanism is the “annefact”. As described above, a signal source which may become a main cause of annefact exists outside the FOV. Hereinafter, an existence region of a signal source which may become the main cause of the annefact is referred to as a “risk region”.

In FIG. 4C, the range of the risk region is schematically indicated by a hatched region surrounded by a bold broken-line frame. If the position Zf within the FOV, the range of the FOV, and the nonlinear function F(Z) are determined, the risk region, i.e., the position Zr and its range of the signal source, which is outside the FOV and has the same frequency as the MR signal emitted from the position Zf within the FOV, can be calculated by the following formula (4).

B0+Gz*Zf=F(Zr) Formula (4)

As is clear from the above described generation mechanism of annefact, when the slice thickness is large, i.e., when the slope of the gradient magnetic field is gentle, it increases the possibility that the range of the magnetic field intensity within the slice as the FOV completely or partially matches with the range of the magnetic field intensity outside the FOV as the non-linear region. This means that the possibility of the presence of a risk region outside the FOV becomes higher. In other words, when the slice thickness is large as shown in FIG. 4C and FIG. 4D, the risk of generating annefact is increased. On the other hand, when the slice thickness is small as shown in FIG. 4A and FIG. 4B, the risk of generating annefact is reduced.

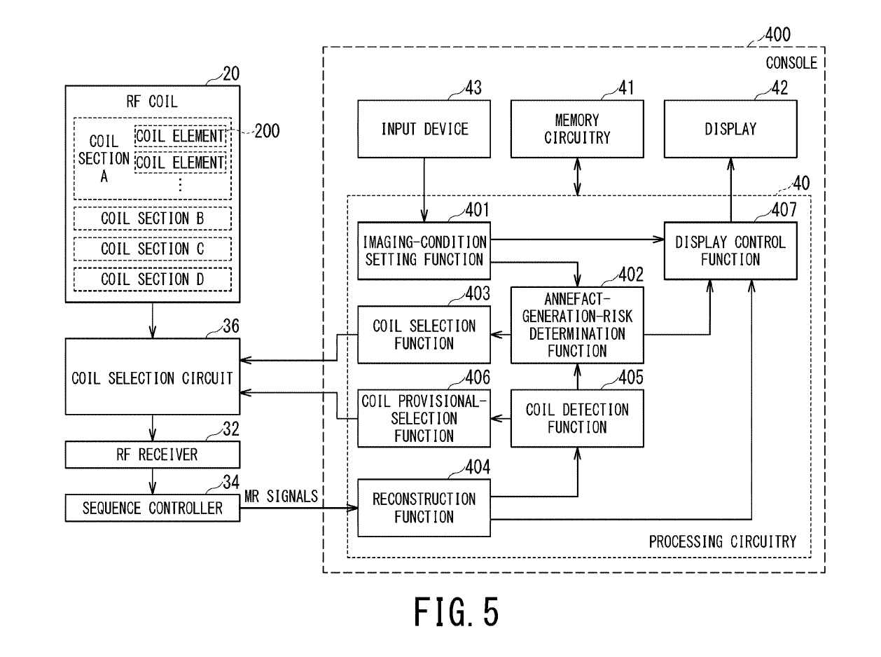

FIG. 5 is a block diagram illustrating detailed configuration of the magnetic resonance imaging apparatus 1 in the first embodiment.

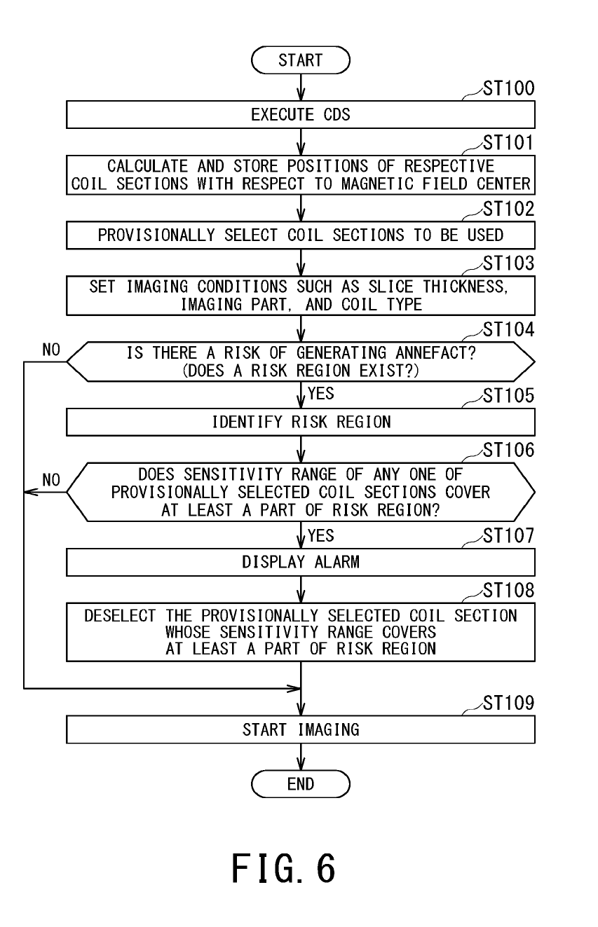

FIG. 6 is a flowchart illustrating an operation performed by the magnetic resonance imaging apparatus 1.

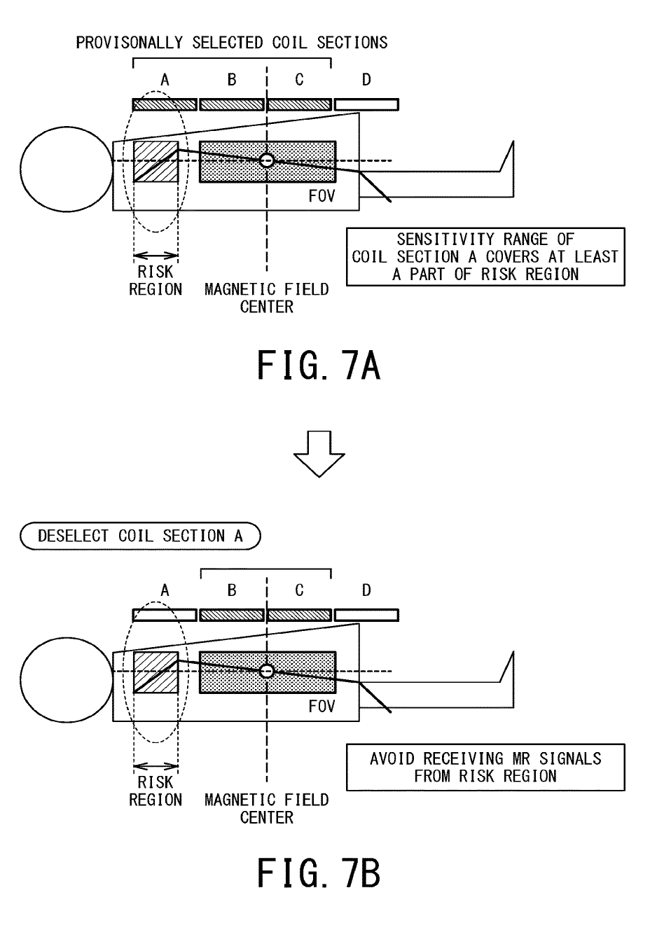

FIG. 7A and FIG. 7B are schematic diagrams illustrating an operational concept of the magnetic resonance imaging apparatus 1 in the first embodiment.

Hereinafter, an operation performed by the magnetic resonance imaging apparatus 1 in the first embodiment will be described in detail by reference to FIG. 5 to FIG. 7B.

The RF coil 20 shown in the upper left part of FIG. 5 includes plural coil elements 200 and these coil elements 200 are grouped into plural coil sections as described above. Although the number of the coil elements 200 and the number of the coil sections are not limited to a specific number, the RF coil 20 has, for example, four coil sections A to D.

The RF coil 20 outputs MR signals detected by the respective coil elements 200 to the RF receiver 32, via the coil selection circuit 36. The RF receiver 32 converts the respective MR signals selected by the coil selection circuit 36 into digital signals, and outputs the digitized MR signals to the sequence controller 34. The sequence controller 34 transmits the digitized MR signals to the console 400.

The console 400 includes the processing circuitry 40, the memory circuitry 41, the display 42, and the input device 43 as described above.

The processing circuitry 40 has an imaging-condition setting function 401, an annefact-generation-risk determination function 402, a coil selection function 403, a reconstruction function 404, a coil detection function 405, a coil provisional-selection function 406, and a display control function 407. The processing circuitry 40 includes a processor which implements each of those functions 401 to 407 by executing predetermined programs stored in the memory circuitry 41, for example. Each of the above-described functions 401 to 407 will be described with reference to the flowchart shown in FIG. 6.

The steps ST100 and ST101 correspond to the processing performed by the coil selection function 403. The coil selection function 403 performs a scan called a CDS (Coil Detection Scan). This CDS is performed in order to identify the position of the RF coil 20 attached to the object, specifically, in order to identify the Z-axis position of each of the coil sections inside the RF coil 20 with respect to the magnetic field center. In the CDS, for example, the object is imaged under one-dimensional FE (Field Echo) type protocol, and then the Z-axis position of each coil section with respect to the magnetic field center is calculated based on the peak value of reconstructed signal intensity obtained by performing one-dimensional Fourier transform on the MR signals from each coil section. Afterward, the calculated Z-axis position of each of the coil sections is stored in the memory circuitry 41. Incidentally, one-dimensional Fourier transform, i.e., Fourier transform in the Z-axis direction is performed by the reconstruction function 404.

The step ST102 corresponds to the processing performed by the coil provisional-selection function 406. On the basis of the position of the magnetic field center, the coil provisional-selection function 406 provisionally selects predetermined number of the coil elements 200 from all the coil elements 200 of the RF coil 20, or provisionally selects predetermined number of coil sections from all the coil sections of the RF coil 20. For example, the coil provisional-selection function 406 provisionally selects the coil sections A, B, and C close to the magnetic field center from a total of four coil sections A to D of the RF coil 20 as shown in FIG. 7A. Afterward, the coil provisional-selection function 406 outputs the selection result to the coil selection circuit 36. Although the positions of the respective coil sections A and D are symmetric about the magnetic field center in the case of FIG. 7A, signal intensity of the coil section A may be determined to be larger than signal intensity of the coil section D as a result of the above-described CDS in some cases. In such cases, the coil section D is deselected, and the coil sections A, B, and C are provisionally selected.

The step ST103 corresponds to processing performed by the imaging-condition setting function 401. The imaging-condition setting function 401 sets various types of imaging conditions based on information and data inputted by an operator via the input device 43. The imaging conditions to be set include a pulse sequence, i.e., a type of protocol, information on the position and size of the FOV, and information on resolution. The size of the FOV includes information on thickness of each slice to be excited. The imaging conditions include information on an anatomical imaging part such as an abdomen, a chest, a spine, a head, an ankle, and a wrist. Additionally, the imaging conditions include information on a coil type of the RF coil 20 such as a body coil, a spine coil, a head coil, a foot coil, and a wrist coil.

The step ST104 corresponds to processing performed by the annefact-generation-risk determination function 402. On the basis of the imaging conditions, the annefact-generation-risk determination function 402 determines a risk of generating annefact, i.e., an artifact caused by mixture of MR signals from outside of the imaging region of the object. Here, at least one of slice thickness, an anatomical imaging part, and a coil type out of the above-described imaging conditions is used for determining the risk of generating annefact.

For example, when slice thickness is larger than a predetermined value, the annefact-generation-risk determination function 402 determines that there is a risk of generating annefact, for the following reason. When slice thickness is large, i.e., when the slope of the gradient magnetic field is gentle, it increases possibility of the presence of the risk region, which is considered to increase the risk of generating annefact according to the generation mechanism of annefact described by reference to FIG. 4. When the annefact-generation-risk determination function 402 determines that there is a risk of generating annefact, the processing proceeds to the step ST105. On the other hand, when slice thickness is smaller than a predetermined value, the annefact-generation-risk determination function 402 determines that a risk of generating annefact is small, the processing proceeds to the step ST109, and imaging is started.

Meanwhile, even in the case where a risk region exists, annefact is not generated unless the risk region is within the sensitivity range of the RF coil 20. This is because MR signals from the risk region are not received by the RF coil 20 if the risk region is outside the sensitivity range of the RF coil 20, as is understood from FIG. 4C.

For the above reason, the annefact-generation-risk determination function 402 determines that there is a risk of generating annefact in cases where the width of the imaging region in the head-foot direction is larger than a predetermined value, for example. A case where the width of an imaging region in the head-foot direction is larger than a predetermined value corresponds to, for example, a case where an anatomical imaging part is a spine, an abdomen, a chest, or a leg. Note that in the case of imaging an imaging region being wide in the head-foot direction, the RF coil 20 having extensive sensitivity range in the head-foot direction is usually used. Thus, the possibility that sensitivity of the RF coil 20 covers or reaches the risk region adjacent to the FOV becomes higher.

For this reason, when the width of an imaging region in the head-foot direction is larger than a predetermined value, the annefact-generation-risk determination function 402 determines that there is a risk of generating annefact and the processing proceeds to the step ST105.

By contrast, when the width of the imaging region in the head-foot direction is smaller than the predetermined value (e.g., when the anatomical imaging part is a head, an ankle region, or a wrist), the annefact-generation-risk determination function 402 determines a risk of generating annefact to be small, the processing proceeds to the step ST109, and imaging is started.

Whether sensitivity of the RF coil 20 sufficiently covers the risk region or not can also be determined based on a type of the RF coil 20. For example, when the coil type is a spine coil or a body coil, sensitivity of the RF coil 20 covers an extensive range in the head-foot direction, the annefact-generation-risk determination function 402 accordingly determines that there is a risk of generating annefact. Then the processing proceeds to the step ST105. By contrast, when the coil type is an RF coil configured to cover only a limited region in the head-foot direction like a head coil, a foot coil, and a wrist coil, the annefact-generation-risk determination function 402 determines a risk of generating annefact to be small, the processing proceeds to the step ST109, and imaging is started.

Although a risk of generating annefact may be determined by separately using slice thickness, an imaging part, and a coil type, it may be determined based on combination of these three factors.

When it is determined that there is a risk of generating annefact, the annefact-generation-risk determination function 402 further determines whether the magnetic resonance frequency range within the imaging region (i.e., the FOV) completely or partially matches with the magnetic resonance frequency range outside the imaging region or not, on the basis of the slope and nonlinearity of the gradient magnetic field corresponding to imaging conditions in the step ST104.

For example, whether the magnetic resonance frequency range within the imaging region (i.e., the FOV) completely or partially matches with the magnetic resonance frequency range outside the imaging region or not can be determined by comparing the magnetic resonance frequency range corresponding to B(Zf) calculated from the formula (2) with the magnetic resonance frequency range corresponding to B(Zr) calculated from the formula (3). When the magnetic resonance frequency range within the FOV completely or partially matches with the magnetic resonance frequency range outside the FOV, the annefact-generation-risk determination function 402 determines that a risk region exists outside the FOV, and thus there is a risk of generating annefact.

Incidentally, the values of B0 and Gz in the formula (2) and the shape of the nonlinear function F(Z) in the formula (3) may be measured and stored in the memory circuitry 41 in advance so that the annefact-generation-risk determination function 402 can refer to the stored values and shape in the step ST104.

The next steps ST105 and ST106 also correspond to processing performed by the annefact-generation-risk determination function 402. When it is determined that a risk region exists and thus there is a risk of generating annefact in the step ST104, the annefact-generation-risk determination function 402 identifies the position and range of the risk region in the step ST105. Specifically, the annefact-generation-risk determination function 402 can calculate the position Zr and range of a signal source of annefact outside the FOV by using the above-described formula (4) and can identify that the calculated position Zr and range as the risk region.

Further, in the step ST106, the annefact-generation-risk determination function 402 determines whether the sensitivity range of provisionally selected coil elements 200 or coil sections completely or partially match with the identified risk region or not. Here, to completely or partially match with the risk region in the above-described determination as to the coil elements 200 or coil sections means that at least a part of the risk region is included in the sensitivity range sufficiently covered by the coil elements 200 or coil sections in terms of the Z-axis position, for example.

When the sensitivity range of provisionally selected coil elements 200 or coil sections completely or partially match with the identified risk region, the annefact-generation-risk determination function 402 identifies the coil element(s) 200 or coil section(s) whose sensitivity range sufficiently covers at least a part of the risk region out of all the provisionally selected coil elements 200 or coil sections. FIG. 7A illustrates a case in which the identified risk region is completely included in the sensitivity range of the provisionally selected coil section A.

The step ST107 corresponds to processing performed by the display control function 407. The display control function 407 causes the display 42 to display an alarm such as “Under the currently selected imaging conditions, there is a risk of generating annefact”, for example. The above-described alarm display may be performed immediately after the step ST104 or immediately after the step ST105.

The step ST108 corresponds to processing performed by the coil selection function 403. The coil selection function 403 deselects the coil element 200 or coil section identified to cover at least a part of the risk region in terms of sensitivity to MR signals in the step ST106. For example, as shown in FIG. 7A, when the coil section A is determined to cover at least a part of the risk region in terms of sensitivity to MR signals, the coil selection function 403 transmits a control signal to the coil selection circuit 36 for deselecting MR signals from the coil section A. Instead of transmitting such a control signal, the coil selection function 403 may output a command signal to exclude MR signals from the coil section A in reconstruction processing to the reconstruction function 404. As a result, the coil section A is excluded from the coil sections, and the remaining coil sections except the coil section A are used for imaging as shown in FIG. 7B. Thus, mixture of an artifact from the risk region outside the FOV, i.e., generation of annefact can be avoided or suppressed.

Incidentally, after the processing of the step ST108, the display control function 407 may cause the display 42 to display an alarm such as “The coil section A is deselected because of possibility of generating annefact”.

Afterward, imaging is started in the step ST109.

As described above, according to the magnetic resonance imaging apparatus 1 of the first embodiment, the risk of generating annefact can be determined based on imaging conditions. Additionally, generation of annefact can be avoided or suppressed by identifying a risk region as a source of generating annefact and deselecting the coil element(s) 200 or the coil section(s) whose sensitivity range covers at least a part of the risk region in terms of the Z-axis position, for example.

Moreover, operational burden is not imposed on a user, because the determination processing as to a risk of generating annefact based on imaging conditions and the processing of deselecting a specific coil element(s) 200 or coil section(s) based on the determination result are automatically performed by the processing circuitry 40.

Although some users do not know the existence of annefact or the generation mechanism of annefact, generation of annefact can be avoided or suppressed without making such a user conscious of annefact.

Furthermore, since a coil element 200(s) or coil section(s) having possibility of causing annefact is excluded before image reconstruction, size of data used in image reconstruction processing is reduced and computation load is reduced.

Although annefact is caused regardless of a type of pulse sequence due to its generation mechanism, the magnetic resonance imaging apparatus 1 of the present embodiment can avoid or suppress generation of annefact regardless of a type of pulse sequence.

In the above description, it is assumed that the coil selection circuit 36 performs the processing of deselecting coil element(s) 200 or coil section(s) whose sensitivity range covers at least a part of the risk region according to control signals inputted from the coil selection function 403. However, the processing of deselecting such a coil element 200 or coil section may be performed by another component aside from the coil selection circuit 36. For example, the processing of deselecting such coil element(s) 200 or coil section(s) may be performed in the former stage prior to the coil selection circuit 36 or may be performed in the subsequent stage posterior to the coil selection circuit 36.

Further, the MR signals corresponding to all the connected coil elements 200 or coil sections may be once transmitted to the reconstruction function 404 of the processing circuitry 40, in such a manner that the reconstruction function 404 does not use the MR signals corresponding to the deselected coil element(s) 200 or coil section(s) in the image reconstruction processing. In other words, a pulse sequence of acquiring MR signals may be executed by using all the connected coil elements or coil sections, and the image reconstruction processing may be performed based on the MR signals acquired from the selected coil elements or coil sections without using the MR signals acquired from the deselected coil element(s) or coil section(s).

### Second Embodiment

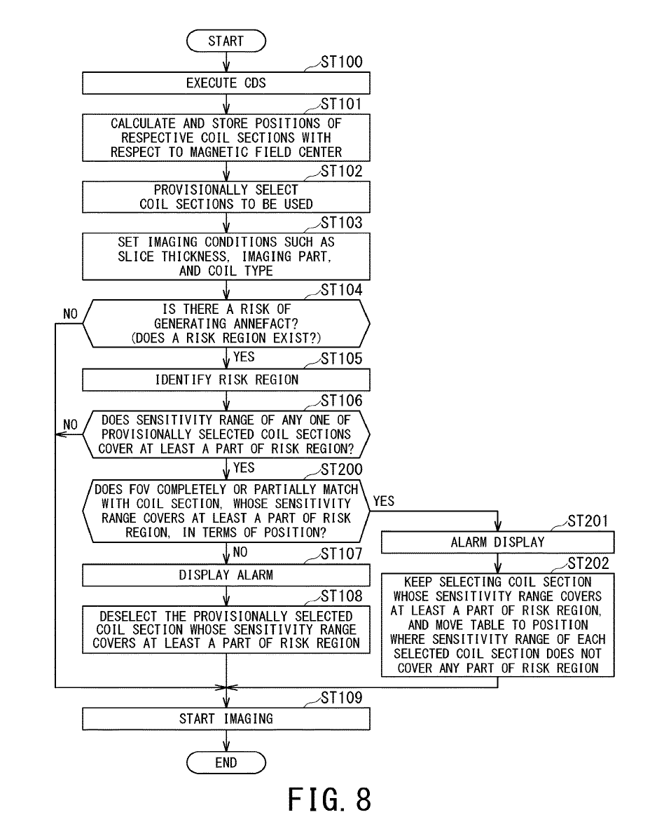

FIG. 8 is a flowchart illustrating an operation performed by the magnetic resonance imaging apparatus 1 of the second embodiment.

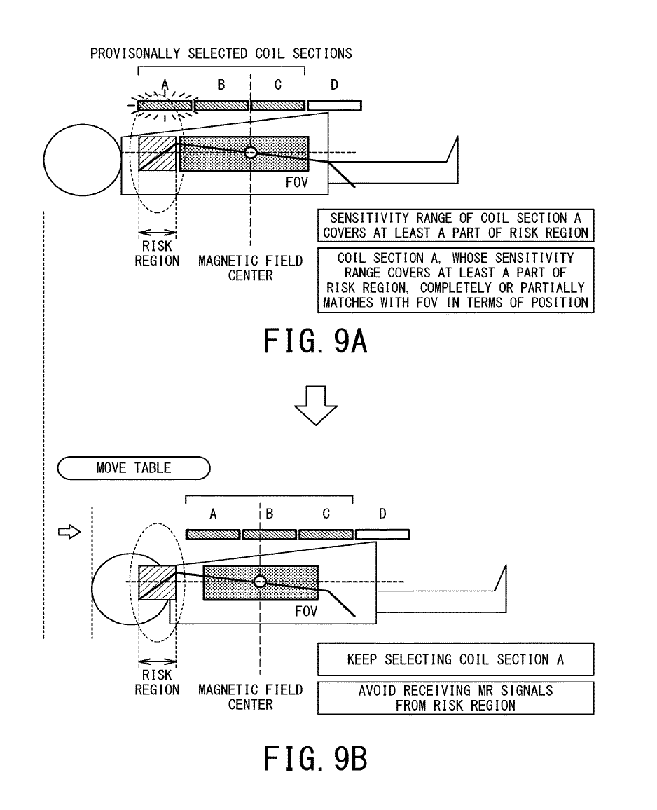

Additionally, FIG. 9A and FIG. 9B are schematic diagrams illustrating an operational concept of the magnetic resonance imaging apparatus 1 of the second embodiment. The same reference number is assigned to the same processing as the first embodiment, and duplicate description is omitted. In the second embodiment, processing from the steps ST200 to ST202 is added to the processing of the first embodiment shown in FIG. 6.

The step ST200 corresponds to processing performed by the annefact-generation-risk determination function 402. When the sensitivity range of the provisionally selected coil elements 200 or coil sections is determined to cover at least a part of the risk region in the step ST106, the annefact-generation-risk determination function 402 further determines whether the coil element 200 or coil section determined to cover at least a part of the risk region matches, completely or partially, with the FOV in the Z-axis position or not in the step ST200. When the coil element 200 or coil section determined to cover at least a part of the risk region matches, completely or partially, with the FOV, the processing proceeds to the step ST201 without deselecting such a coil element 200 or coil section.

In the case shown in FIG. 9A, the provisionally selected coil section A covers at least a part of the risk region and a part of this coil section A partially matches with the FOV in the Z-axis position. In such a case, the processing proceeds to the step ST201 without deselecting the coil section A. This is because there is a possibility that some MR signals from the FOV cannot be received in the case of deselecting the coil section A.

Even in such a case, reception of MR signals from the risk region can be avoided by moving the table 51 of the bed 500 in the head-foot direction (i.e., the Z-axis direction) under the condition where the coil section A is kept selected, as shown in FIG. 9B.

The step ST201 corresponds to processing performed by the display control function 407. The display control function 407 causes the display 42 to display an alarm and/or a message prompting movement of the table such as “Since there is a risk of generating annefact, please move the table”.

Additionally, for example, the display control function 407 may cause the display 42 to display a message screen in which figures, e.g., as shown in FIG. 9A and/or FIG. 9B are depicted. For example, when the coil section A covers both the risk region and the FOV, the display control function 407 may cause the area of the coil section A in the message screen blink for attracting attention, as shown in FIG. 9, while displaying a message such as “Since there is a risk of generating annefact, please move the table”.

An operator moves the table according to such a guidance display (i.e., the message screen). Then, the position of the RF coil 20 including the coil section A leaves from the risk region according to the movement of the table 51, and the coil section A is finally located at a position where its sensitivity range does not cover any part of the risk region. In the period during which the table 51 is moved, the determination processing of the step ST200 is continuously repeated until blinking of the coil section A on the display 442 is stopped, when the coil section A is moved to a position where its sensitivity range does not cover any part of the risk region (step ST202). An operator can recognize the timing to stop moving the table 51 by the stop of the blinking on the display 42.

According to the magnetic resonance imaging apparatus 1 of the second embodiment, the effects of the first embodiment can be obtained. Further, in the second embodiment, generation of annefact can be avoided or suppressed even if a coil element 200 or coil section covers both the risk region and the FOV.

According to the magnetic resonance imaging apparatus of at least one of the above-described embodiments, generation of an artifact attributable to nonlinearity of each gradient magnetic field can be avoided or suppressed.

Incidentally, the coil sections in each of the above-described embodiments are aspects of the coil element or section recited in the claims.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
an RF coil equipped with a plurality of coil elements; and
processing circuitry configured to
determine a risk of generating artifact caused by mixture of a magnetic resonance signal outside an imaging region of an object, based on imaging conditions, and
select at least one coil element used for generating an image of the object from the plurality of coil elements, based on a result of determination of the risk of generating artifact.

2. The magnetic resonance imaging apparatus according to claim 1,
wherein the imaging conditions include at least one of slice thickness, an anatomical imaging part, and a type of the RF coil, and
the processing circuitry is configured to determine the risk of generating artifact by using the at least one of the slice thickness, the anatomical imaging part, and the type of the RF coil.

3. The magnetic resonance imaging apparatus according to claim 2,
wherein the processing circuitry is configured to determine that there exists the risk of generating the artifact, when the slice thickness is larger than predetermined thickness.

4. The magnetic resonance imaging apparatus according to claim 2,
wherein the processing circuitry is configured to determine that there exists the risk of generating the artifact, when width of the anatomical imaging part in a head-foot direction is larger than predetermined width, or when the RF coil belongs to a coil type of imaging an anatomical imaging part whose width in the head-foot direction is larger than the predetermined width.

5. The magnetic resonance imaging apparatus according to claim 1,
wherein the plurality of coil elements are divided into a plurality of sections defined in an arrangement unit in a head-foot direction, and
the processing circuitry is configured to sort select at least one of the plurality of coil elements to be used for imaging the object by selecting at least one of the plurality of sections.

6. The magnetic resonance imaging apparatus according to claim 1,
wherein the processing circuitry is configured to
determine whether a magnetic resonance frequency range in the imaging region completely or partially matches with a magnetic resonance frequency range outside the imaging region or not, by using a slope and nonlinearity of a gradient magnetic field corresponding to the imaging conditions, and
determine that there exists the risk of generating artifact, when the magnetic resonance frequency range inside the imaging region completely or partially matches with a magnetic resonance frequency range outside the imaging region.

7. The magnetic resonance imaging apparatus according to claim 6,
wherein the processing circuitry is configured to
identify a region outside the imaging region whose magnetic resonance frequency range completely or partially matches with the magnetic resonance frequency range inside the imaging region, as a risk region which has a possibility of including a signal source of artifact,
determine whether each of the plurality of coil elements covers at least a part of the identified risk region or not, and
select each coil element which is determined not to cover any part of the risk region, as coil elements to be used for imaging the object, while deselecting each coil element which is determined to cover at least a part of the risk region.

8. The magnetic resonance imaging apparatus according to claim 1,
wherein the processing circuitry is configured to
provisionally select predetermined number of coil elements from the plurality of coil elements based on a position of a magnetic field center, before finally selecting coil elements used for imaging the object, and
determine whether the provisional selection is maintained or deselected, based on a result of determination of the risk of generating artifact.

9. The magnetic resonance imaging apparatus according to claim 7,
wherein the processing circuitry is configured to
provisionally select predetermined number of coil elements from the plurality of coil elements based on a position of a magnetic field center, before finally selecting coil elements used for imaging the object, and
select each coil element which is determined not to cover any part of the risk region while deselecting each coil element covering at least a part of the risk region, out of the predetermined number of coil elements provisionally selected.

10. The magnetic resonance imaging apparatus according to claim 7,
wherein the processing circuitry is configured to
further determine whether each coil element determined to cover at least a part of the risk region completely or partially matches with the imaging region or not, and
keep selecting each coil element, which is determined to cover at least a part of the risk region and is also determined to completely or partially match with the imaging region, as a coil element used for imaging the object.

11. The magnetic resonance imaging apparatus according to claim 10, further comprising a display and a table on which the object is loaded,
wherein the processing circuitry is configured to cause the display to display at least one of an alarm and a message for prompting movement of the table, when at least one coil element determined to cover at least a part of the risk region is further determined to completely or partially match with the imaging region.
